(19) United States
(12) Patent Application Publication
(10) Pub. No.: US 2012/0211856 A1
(43) Pub. Date: Aug. 23, 2012

(54) PHOTOVOLTAIC CELL CONDUCTOR CONSISTING OF TWO, HIGH-TEMPERATURE AND LOW-TEMPERATURE, SCREEN-PRINTED PARTS

(75) Inventors: Armand Bettinelli, Coublevie (FR); Yannick Veschetti, Concarneau (FR)

(73) Assignee: COMMISSARIAT A L'ENERGIE ATOMIQUE ET AUX ENERGIES ALTERNATIVES, Paris (FR)

(21) Appl. No.: 13/504,398

(22) PCT Filed: Nov. 5, 2010
(86) PCT No.: PCT/EP2010/066863

§ 371 Date: Apr. 26, 2012

(30) Foreign Application Priority Data
Nov. 6, 2009 (FR) 09 57870

(51) Int. Cl. H01L 23/482; H01L 31/0224; H01L 21/283

(52) U.S. Cl. 257/459; 438/652; 257/762; 257/E21.158; 257/E23.017; 257/E31.124

(57) ABSTRACT

Method for formation of at least one electrical conductor on a semiconductor material (1), characterized in that it comprises the following steps:
(E1)—deposition by serigraphy of a first high-temperature paste;
(E2)—deposition by serigraphy of a second low-temperature paste at least partially superposed onto the first high-temperature paste deposited during the preceding step.

The invention relates to a method for formation of a conducting track on a semiconductor material and also to the resulting semiconductor element. It notably relates to a photovoltaic cell as such obtained by this method.

A photovoltaic cell is fabricated starting from a wafer of semiconductor material, generally silicon. This fabrication necessitates, in particular, the formation of electrical conductors on the surface of this wafer. For this purpose, one method of the prior art consists in depositing a conducting ink by a silkscreen printing, or serigraphic, process onto the wafer. This method has the advantage of its simplicity and of its low cost.

A first technique for metallization by serigraphy consists in the use of a conducting ink taking the form of a paste referred to as “high-temperature paste” with reference to the method implemented which comprises a final step which consists in raising the paste to a high temperature after its application, above 500° C., generally between 700 and 800° C. Such a high-temperature paste generally comprises silver and potentially aluminium, for its conducting property, particles of glass, whose function is to break through an insulating layer in order to make an electrical contact on the semiconductor, and organic components, such as resin dissolved in one or more additive solvents, whose function is to endow the paste with a satisfactory rheological property. The step for heating such a paste to a high temperature allows the silver to be densified and an insulating layer to be broken through in order to finally obtain an electrical contact and a good adhesion. The organic components are burnt or evaporated during this heating. The “high-temperature” pastes are currently used on photovoltaic cells based on crystalline silicon (excluding heterojunction cells).

A second technique for metallization by serigraphy consists in the use of a conducting ink in the form of a paste referred to as “low-temperature paste” with reference to the method implemented which comprises a final step that consists in bringing the paste to low temperature after its application, below 500° C. and generally under 300° C. Such a paste is used for cells comprising amorphous silicon, such as the cells referred to as “thin-film cells” and heterojunction crystalline cells which cannot withstand high temperatures. A low-temperature paste comprises particles of silver, for its conducting property, and organic components in order to exhibit a good rheology. Such a paste has a high resistivity and hence a poor conducting property.

The use of existing conducting inks is restricted to limited applications owing to their low conducting properties.

Thus, this technique is not for example currently used for junction cells and contacts on the back face of a crystalline silicon substrate. These cells have the advantage of a high efficiency owing to the reduction of the shadowing by eliminating the metallizations generally present on the front face of the cells. The document US2004/0200520 presents such a solution. However, the solution described in this document has the drawback of being very complex because the conductors are formed by sputtering of three metals and by a copper-based electrolytic recharging. Thus, the production throughput of this solution is limited and its cost is high.

Accordingly, a general object of the invention is to provide a solution for formation of an electrical conductor by serigraphy which allows a broader implementation.

More precisely, the invention endeavours to achieve all or part of the following objectives:

A first object of the invention is to provide a solution for formation of an electrical conductor by serigraphy on a photovoltaic cell allowing a good electrical conduction and a high efficiency of the photovoltaic cell to be achieved by reason of a reduced electrical contact surface area.

A second object of the invention is to provide a solution for formation of an electrical conductor by serigraphy on a photovoltaic cell by an efficient and low-cost method with high productivity.

For this purpose, the invention is based on a method for formation of at least one electrical conductor on a semiconductor material, characterized in that it comprises the following steps:
(E1)—deposition by serigraphy of a first high-temperature paste;
(E2)—deposition by serigraphy of a second low-temperature paste at least partially superposed onto the first high-temperature paste deposited during the preceding step.

The first step can comprise the heating of the first serigraphed high-temperature paste to a temperature greater than 500° C. and the second step (E2) can comprise the heating of the second serigraphed low-temperature paste to a temperature lower than 500° C.

According to one advantageous variant, the first step can comprise the heating of the first serigraphed high-temperature paste to a temperature greater than 700° C. and the second step can comprise the heating of the second serigraphed low-temperature paste to a temperature lower than 300° C.

The first step can comprise the deposition of a high-temperature paste onto an insulating layer situated on the surface of the semiconductor material so as to be superposed onto a doped region positioned under the insulating layer in such a manner that the heating of the first serigraphed high-temperature paste allows this insulating layer to be broken through so as to obtain the electrical contact with the doped region positioned under the insulating layer.

The second step can comprise the deposition of the low-temperature paste onto the insulating layer situated on the surface of the semiconductor material, in such a manner that the heating of the second serigraphed low-temperature paste does not break through the insulating layer.

The invention also relates to a semiconductor material comprising at least one electrical conductor characterized in that the electrical conductor comprises a first part comprising a serigraphed high-temperature paste and a second part comprising a serigraphed low-temperature paste at least partially covering the first part.

The serigraphed high-temperature paste can comprise a metal part comprising silver and aluminium or only silver, and the serigraphed low-temperature paste can comprise one or more metals, such as silver, aluminium and/or copper.

The serigraphed high-temperature paste can comprise particles of glass.

The first part of the conductor comprising the serigraphed high-temperature paste can be in electrical contact with a doped well present within the semiconductor material covered by an insulating layer except under the first part.

The second part of the conductor comprising the serigraphed low-temperature paste can be wider than the first part.

The conductor can have a cross section in the form of a mushroom, whose first part represents the foot and second part the head. The width of the head of the conductor can be at least twice the width of the foot.

The first part of the conductor comprising a serigraphed high-temperature paste can form one or more continuous or discontinuous strip(s) over the entire width of the semiconductor material.

The semiconductor material comprising at least one electrical conductor can be a photovoltaic cell.

In this case, it can comprise a back face on which are arranged two wells with opposing electrical doping, the back face being covered by an insulating layer, and it can comprise two conductors each comprising a first part with serigraphed high-temperature paste in contact with a well within the thickness of the insulating layer and comprising a second part with serigraphed low-temperature paste in contact with the first part of the conductor and lying on the surface of the insulating layer and forming a cathode and an anode.

The at least one well can have a width equal to at least twice the width of the first part of the conductor.

These objects, features and advantages of the present invention will be presented in detail in the following description of one particular embodiment, by way of non-limiting example, in relation with the appended figures amongst which:

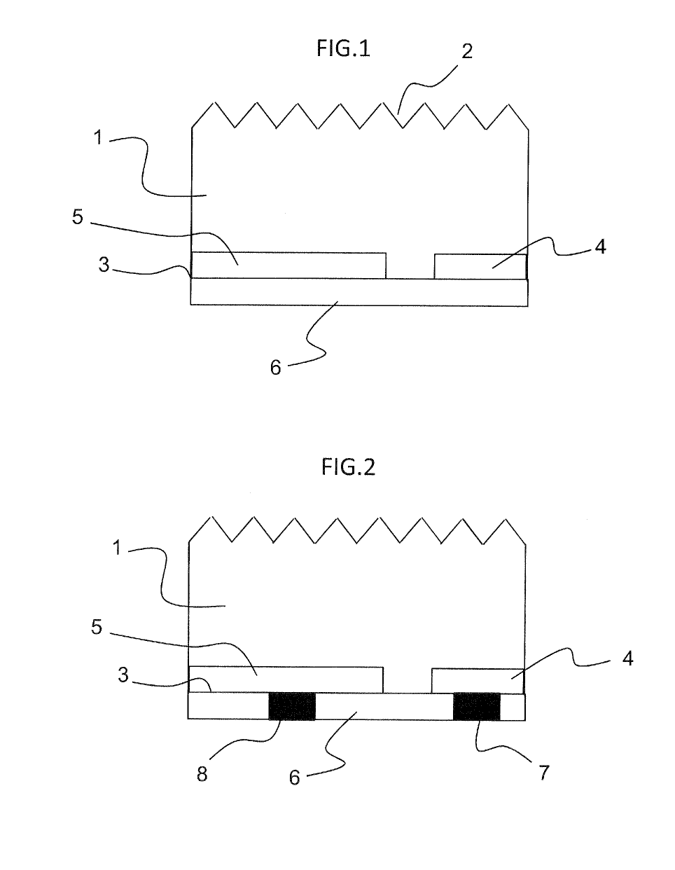

FIG. 1 illustrates schematically a cross-sectional side view of a photovoltaic cell with rear contacts in a phase of fabrication prior to the formation of the conductors according to one embodiment of the invention.

FIG. 2 shows schematically a cross-sectional side view of the photovoltaic cell with rear contacts after a first step for formation of the conductors according to the embodiment of the invention.

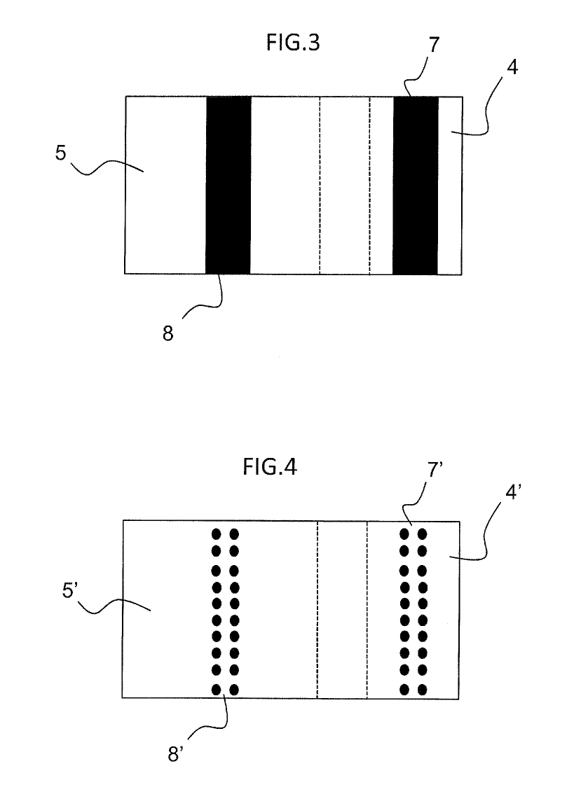

FIG. 3 shows schematically a view of the back face of the photovoltaic cell with rear contacts after the first step for formation of the conductors according to the embodiment of the invention.

FIG. 4 shows schematically a view of the back face of a photovoltaic cell with rear contacts after a first step for formation of the conductors according to a first variant of the embodiment of the invention.

FIG. 5 shows schematically a view of the back face of a photovoltaic cell with rear contacts after a first step for formation of the conductors according to a second variant of the embodiment of the invention.

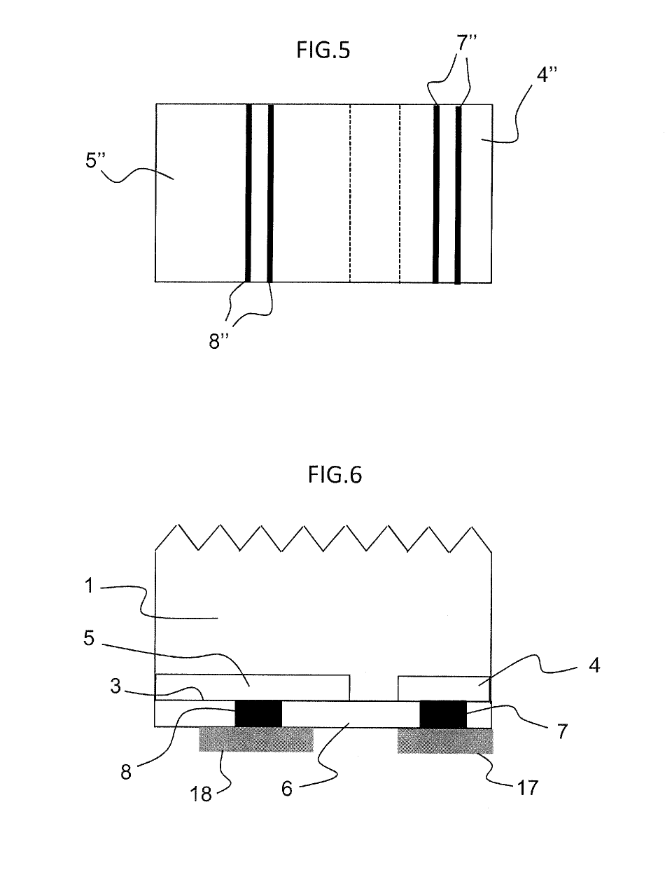

FIG. 6 shows schematically a cross-sectional side view of the photovoltaic cell with rear contacts after a second step for formation of the conductors according to the embodiment of the invention.

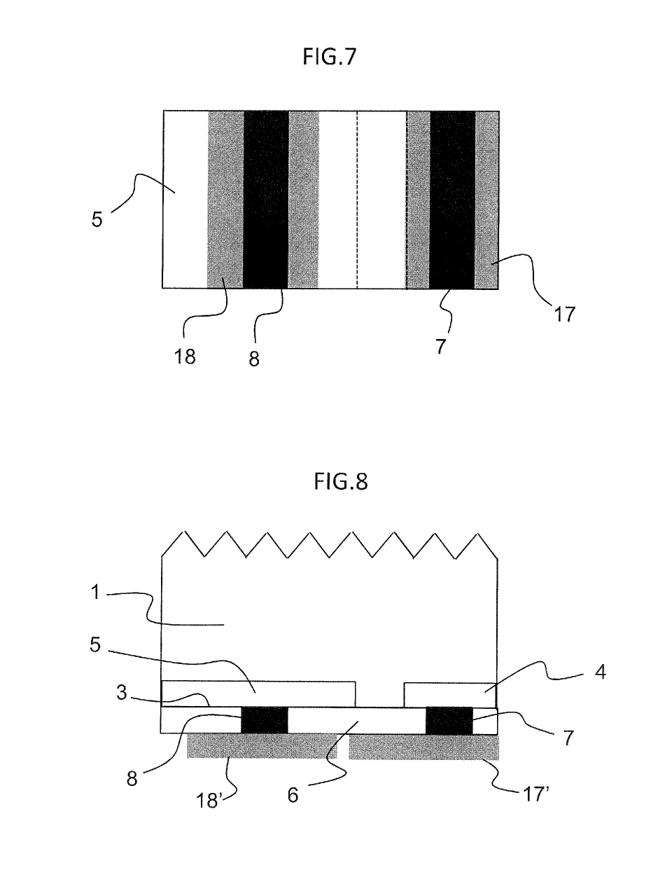

FIG. 7 shows schematically a view of the back face of the photovoltaic cell with rear contacts after the second step for formation of the conductors according to the embodiment of the invention.

FIG. 8 shows schematically a cross-sectional side view of the photovoltaic cell with rear contacts according to one variant of the embodiment of the invention.

The invention is based on the combined use of the two pastes at high and low temperature on the same semiconductor component so as to simply obtain one or more conductor(s) by serigraphy with no detriment to the overall structure of the semiconductor component while at the same time obtaining a conductor with satisfactory conducting property.

The invention will be illustrated by way of example in the framework of a photovoltaic cell with rear contacts. However, it remains suitable for implementation on any type of photovoltaic cell and, more generally, for the fabrication of any electronic component requiring the formation of conductors on a semiconducting structure.

FIG. 1 shows a photovoltaic cell in one phase of fabrication. It comprises a textured front face 2 and a polished back face 3. The front face 2 has a specific treatment for limiting the energy losses by recombination. The silicon wafer 1 forming the semiconductor substrate of the photovoltaic cell may be of the P or N type, preferably single-crystal. Doping wells 4, 5 are distributed in a symmetric manner on the back face 3 of the photovoltaic cell 1. The well 4 has the same type of doping as the substrate 1 of the photovoltaic cell, whereas the well 5 has an opposite doping to that of the substrate. Finally, one or more insulating layer(s) of dielectric forming an insulating passivation layer 6 is/are added on the back face 3.

The finalization of the photovoltaic cell, shown in FIG. 1, requires the formation of the metal conductors, notably for electrically connecting the wells 4 and 5 to the outside.

FIGS. 2 and 3 show a first step E1 of the method for formation of the metal conductors according to the embodiment of the invention. This step consists in depositing by serigraphy a high-temperature paste in order to form first contacts 7, 8 respectively allowing the wells 4, 5 to be reached through the layer of dielectrics 6. Indeed, after high-temperature treatment of the paste used, for example by means of an infrared oven, it penetrates through the insulating layer 6 to reach the wells 4, 5. Advantageously, the high-temperature paste used for contacting the wells doped with boron (p+) will be composed of silver and aluminium (1-2%), and the paste used for contacting the wells doped with phosphorus (n+) will be composed of silver.

The resulting serigraphed conductors 7, 8 consist of strips occupying the whole width of the photovoltaic cell, such as is shown in FIG. 3, positioned facing the central part of the wells 4, 5, respectively. These strips do not necessarily need to occupy the entire width. Advantageously, the contacts strips 7, 8 have a width that is reduced with respect to the width of the wells 4, 5. For example, for wells of width in the range between 0.5 and 1.5 mm, the contact strips 7, 8 can have a width in the range between 100 and 200 μm and, more generally, less than 300 μm. More generally, it is advantageous for the width of at least one well to be equal to at least twice the width of a contact strip. In the figures, the dimensions of these contact strips are purposely exaggerated for reasons of clarity of presentation.

FIGS. 4 and 5 show variant embodiments of these first contacts. Thus, FIG. 4 shows contacts with two times two strips of discontinuous contacts 7′, 8′. FIG. 5 shows a second variant in which each contact consists of two continuous strips 7″, 8″ of smaller dimensions. These two solutions allow the contact surface area to be reduced.

In any case, the optimal situation for making the contacts is to position the various contacts in the central region of the doping wells 4, 5, in order to limit the resistive losses.

FIGS. 6 and 7 show the second and last step E2 of the method for formation of the conductors according to the embodiment of the invention. It consists in depositing by serigraphy a low-temperature paste in order to form the anode 17 and cathode 18 of the photovoltaic cell. These contacts 17, 18 are naturally superposed onto the first contacts 7, 8 in order to obtain an electrical link from the wells 4, 5 to the contacts 17, 18, respectively.

The low-temperature paste is raised to a low temperature of around 200° C. As this low-temperature paste does not penetrate into the dielectric layer 6, it is possible to form very wide contacts 17, 18 with this paste, which is advantageous for increasing the conductivity of the conductors thus formed. This low-temperature paste can comprise one or more metals, such as silver, aluminium and/or copper. It may also take a different form.

The low-temperature paste used in this second step therefore has the advantage of not breaking through the dielectric layer 6, which allows a further increase in its width to be envisaged and potentially even that the dimensions of the well that it connects be exceeded. FIG. 8 thus illustrates such a solution, in which the second contacts 18′ are very wide and much greater than the width of the well 4.

Thus, the embodiment described is therefore based on the formation of conductors whose cross section has a mushroom shape, comprising a first narrow part, or foot, formed using a high-temperature serigraphy, and a second part, or head, formed using a low-temperature serigraphy. The width of the head of the conductor can advantageously be at least twice the width of the foot. The combination of these two types of serigraphy allows an optimal result to be obtained: the fabrication method is simple because it avoids the step for opening of the insulating layer and the conductors obtained exhibit a very satisfactory conducting property.

In addition, the chosen solution allows a limited contact surface area to be obtained in the wells, which is favourable for the performance of the photovoltaic cell by avoiding recombination phenomena. For this purpose, the width of the high-temperature conductors is chosen to be of minimum size so as to ensure good contacts while at the same time minimizing the break-through of the insulating layer 6 in order to conserve a large passive surface area. In addition, this reduced width of the tracks formed from a high-temperature paste (for example from 100 to 200 μm) allows the warping effects generated during the cooling of these tracks, after their densification at high temperature, to be reduced. Moreover, this paste can be deposited over a reduced thickness (1 to 5 μm) so as to further reduce the warping effect. It does however allow a satisfactory conducting property to be obtained owing to the broadening of the conductor on the outer face. Thus, the contacts using low-temperature serigraphy on the contrary exhibit a maximum width which minimizes the resistance so as to achieve an optimum conducting property. This solution therefore has the advantage of remaining compatible with the usual dimensions of the doping wells for photovoltaic cells with a width of the order of 1 mm.

As a complementary option, this solution is also compatible with a galvanic recharging by cathodic contact of the contact regions which are coated with the same material—the polymerized low-temperature paste.

It is of course possible for the concept of the invention to be implemented in embodiments other than that previously described.

The invention accordingly relates to any method for formation of at least one electrical conductor on a semiconductor material, comprising the following essential steps:
E1—deposition by serigraphy of a first high-temperature paste;
E2—deposition by serigraphy of a second low-temperature paste at least partially superposed onto the first high-temperature paste deposited during the preceding step.

Finally, the solution allows the following advantages to be procured:
the serigraphy of a low-temperature paste onto a high-temperature paste allows the resistivity of tracks with low conductivity to be reduced, notably the conducting tracks obtained with the high-temperature pastes used for contacting N+ doped elements;
the serigraphy of a low-temperature paste onto a high-temperature paste containing aluminium allows an interface with no aluminium to be obtained which becomes compatible with a recharging process in galvanic processes;
when several high-temperature pastes are used to form various conductors, the serigraphy of a low-temperature paste onto these various high-temperature pastes, which may be different, in the end allows contacts to be obtained having a uniform layer over the entire surface of the cell, which is favourable for potential later processing steps such as recharging in galvanic processes.

1. Method for formation of at least one electrical conductor on a semiconductor material, which comprises the following steps:
(E1)—deposition by serigraphy of a first high-temperature paste;
(E2)—deposition by serigraphy of a second low-temperature paste at least partially superposed onto the first high-temperature paste deposited during the preceding step.

2. Method for formation of at least one electrical conductor on a semiconductor material according to claim 1, wherein the first step (E1) comprises the heating of the first serigraphed high-temperature paste to a temperature greater than 500° C. and in that the second step (E2) comprises the heating of the second serigraphed low-temperature paste to a temperature lower than 500° C.

3. Method for formation of at least one electrical conductor on a semiconductor material according to claim 2, wherein the first step (E1) comprises the heating of the first serigraphed high-temperature paste to a temperature greater than 700° C. and in that the second step (E2) comprises the heating of the second serigraphed low-temperature paste to a temperature lower than 300° C.

4. Method for formation of at least one electrical conductor on a semiconductor material according to claim 1, wherein the first step (E1) comprises the deposition of a first high-temperature paste onto an insulating layer situated on the surface of the semiconductor material so as to be superposed on a doped region positioned under the insulating layer in such a manner that the heating of the first serigraphed high-temperature paste allows this insulating layer to be broken through so as to obtain the electrical contact with the doped region positioned under the insulating layer.

5. Method for formation of at least one electrical conductor on a semiconductor material according to claim 4, wherein the second step (E2) comprises the deposition of the second low-temperature paste onto the insulating layer situated on the surface of the semiconductor material, in such a manner that the heating of the second serigraphed low-temperature paste does not break through the insulating layer.

6. Semiconductor material comprising at least one electrical conductor wherein the electrical conductor comprises a first part comprising a serigraphed high-temperature paste and a second part comprising a serigraphed low-temperature paste at least partially covering the first part.

7. Semiconductor material according to claim 6, wherein the serigraphed high-temperature paste comprises a metal part comprising silver and aluminium or only silver, and in that the serigraphed low-temperature paste comprises one or more metals, such as silver, aluminium and/or copper.

8. Semiconductor material according to claim 7, wherein the serigraphed high-temperature paste comprises particles of glass.

9. Semiconductor material according to claim 6, wherein the first part of the conductor comprising the serigraphed high-temperature paste is in electrical contact with a doped well present within the semiconductor material covered by an insulating layer except under the first part.

10. Semiconductor material according to claim 9, wherein the second part of the conductor comprising the serigraphed low-temperature paste is wider than the first part.

11. Semiconductor material according to claim 10, wherein the conductor has a cross section in the form of a mushroom, whose first part represents the foot and second part the head.

12. Semiconductor material according to claim 11, wherein the width of the head of the conductor is at least twice the width of the foot.

13. Semiconductor material according to claim 7, wherein the first part of the conductor comprising a serigraphed high-temperature paste forms one or more continuous or discontinuous strip(s) over the entire width of the semiconductor material.

14. Semiconductor material according to claim 7, wherein the semiconductor material comprising at least one electrical conductor is a photovoltaic cell.

15. Semiconductor material according to claim 14, which comprises a back face on which are arranged two wells with opposing electrical doping, in that the back face is covered by an insulating layer, and in that it comprises two conductors each comprising a first part with serigraphed high-temperature paste in contact with a well in the thickness of the insulating layer and comprising a second part with serigraphed low-temperature paste in contact with the first part of the conductor and lying on the surface of the insulating layer and forming a cathode and an anode.

16. Semiconductor material according to claim 15, wherein at least one well has a width equal to at least twice the width of the first part of the conductor.
